(19) United States
(12) Patent Application Publication
(10) Pub. No.: US 2002/0090772 A1
(43) Pub. Date: Jul. 11, 2002

(54) Method for manufacturing semiconductor lamination, method for manufacturing lamination, semiconductor device, and electronic equipment

(75) Inventor: Seiichiro Higashi, Nagano (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/011,292

(22) Filed: Dec. 11, 2001

(30) Foreign Application Priority Data
Dec. 11, 2000 (JP) 2000-376293
Feb. 8, 2001 (JP) 2001-032513
Dec. 11, 2001 (JP) 2001-376993

(51) Int. Cl. H01L 21/00; H01L 21/84

(52) U.S. Cl. 438/166; 438/487; 257/53

(57) ABSTRACT

A method for manufacturing a lamination of, for example, semiconductors according to the present invention comprises the step of performing light radiation on a second semiconductor layer formed over a first semiconductor layer, or on both the first semiconductor layer and the second semiconductor layer. This step induces a structural change in at least a part of the second semiconductor layer and causes defect-free strain semiconductor crystals to be formed in the formed second semiconductor layer. This method for manufacturing the lamination makes it possible to form the strain semiconductor crystals in a larger area at low cost and even through a simple process.

### BACKGROUND OF THE INVENTION

1. Field of the Invention

The present invention relates to a method for manufacturing a lamination composed of a plurality of substance layers, and also relates to a device such as a field-effect transistor which utilizes the lamination, and to electronic equipment comprising such device.

2. Description of the Related Art

It is known that when crystal growth of a substance such as a semiconductor is produced on a base layer having a different constituent element, a semiconductor having a different structure from its intrinsic structure can be obtained because of the difference in structural parameters such as a lattice constant. As examples of the crystal growing method, a molecular beam epitaxy method and a CVD method have been employed. As shown in FIG. 7, the conventional crystal growing methods have adopted the method of precisely depositing atomic layers 102 through 104 one by one (layer by layer) over a base layer 101.

However, since the atomic layers are deposited one by one by the conventional crystal growing methods, the crystal growth requires much time. If any impurities are mixed in a crystal growing surface, the crystal growth will be inhibited. Accordingly, there is such a drawback that an ultrahigh vacuum of 10⁻⁹ Torr will be required, thereby complicating the device structure.

### SUMMARY OF THE INVENTION

It is a first object of the present invention to provide a method for easily crystallizing, or causing crystal growth of, a lamination including a plurality of semiconductors over a base layer which has different structural parameters such as a lattice constant.

It is a second object of this invention to provide a semiconductor device such as a field-effect transistor having excellent electronic properties such as carrier mobility.

It is a third object of this invention to provide electronic equipment comprising a semiconductor device which is manufactured by a manufacturing method of this invention and which has excellent electronic properties.

In order to achieve the first object, a method for manufacturing a semiconductor lamination according to a first invention comprises the step of performing light radiation on a second semiconductor layer formed over a first semiconductor layer, thereby inducing a structural change in at least a part of the second semiconductor layer. Accordingly, since the second semiconductor layer is formed over the first semiconductor layer, the structural change of the second semiconductor layer tends to be easily influenced by the first semiconductor layer which is the base layer.

The method for manufacturing a semiconductor lamination according to the above-described first invention includes, in addition to the case of light radiation strictly of only the second semiconductor layer, a case in which light radiation of the first semiconductor layer is performed through the second semiconductor layer.

In this entire specification, the term “semiconductor lamination” means a lamination including at least two semiconductor layers (including thin-film semiconductors), and a lamination in which another substance layer exists under the first semiconductor layer is also within the scope of application of this invention. Moreover, a lamination in which another substance layer exists under the second semiconductor layer is also within the scope of application of this invention.

The “structural change” means general phenomena induced by the light radiation, which includes microscopic phenomena such as reactions or generation of lattice defects, and macroscopic phenomena such as melting, crystallization, or recrystallization. This “structural change” does not necessarily consist of only one phenomenon, but may include a plurality of phenomena. For example, a series of substance changes upon crystallization after melting are also defined as “structural change” in this specification.

By the above-described method for manufacturing a semiconductor lamination according to the first invention, the induction of the structural change is influenced by the first semiconductor layer. Since the structural change by the light radiation of the second semiconductor layer is subject to the influence of the first semiconductor layer, such structural change tends to be different from that induced by light radiation of any single-layer semiconductor corresponding to the second semiconductor layer.

The influence upon the structural change of the first semiconductor layer means that, due to influence of the structure, lattice constant, specific heat, carrier mobility, electron donating capability, and electron accepting capability of the first semiconductor layer, or due to influence of, for example, chemical affinity of an element constituting the first semiconductor layer for an element constituting the second semiconductor layer, the crystallization, melting, generation of lattice defects or reactions of the second semiconductor layer turns out to be different from the structural change unique to the second semiconductor layer or of any corresponding single-layer semiconductor. Moreover, the substance structure of an area formed by the structural change under the influence of the first semiconductor layer also tends to be subject to the influence of the first semiconductor layer. This can be examined by various structural analysis means such as X-ray diffraction structural analysis, electron beam diffraction structural analysis, neutron diffraction structural analysis, infrared vibration spectroscopy, or Raman vibration spectroscopy. The substance structure is also reflected in photoelectron properties such as carrier mobility or a photoelectric conversion ratio, so the above-described influence on the substance structure can be estimated by examining the photoelectron properties.

A method for manufacturing a semiconductor lamination according to a second invention comprises the step of performing light radiation of a second semiconductor layer formed over a first semiconductor layer, thereby crystallizing at least apart of the second semiconductor layer. Accordingly, the crystallization is influenced by the first semiconductor layer, and it is possible to form, in the second semiconductor layer, an area which has a different crystal structure from the crystal structure unique to the second semiconductor layer. In this specification, the term “crystallization” means not only crystallization from an amorphous state, but also includes crystallization from a polycrystal or single-crystal state.

By the method for manufacturing the semiconductor lamination according to the second invention, the crystallization is influenced by the first semiconductor layer. Accordingly, it is possible to form, in the second semiconductor layer, an area which has a different crystal structure from the crystal structure unique to the second semiconductor layer or of any corresponding single-layer semiconductor.

By any one of the above-described methods for manufacturing the semiconductor lamination according to this invention, a semiconductor layer having a crystalline area is used as the first semiconductor layer. A regular substance structure of the crystalline area existing in the first semiconductor layer tends to easily perturb at the time of the structural change, particularly the time of crystallization.

By any one of the above-described methods for manufacturing the semiconductor lamination according to this invention, a semiconductor layer made of a single crystal is used as the first semiconductor layer. Specifically speaking, at the time of the structural change, such as crystallization, of the second semiconductor layer, the second semiconductor layer tends to be easily perturbed by the regular substance structure of the first semiconductor layer.

By any one of the above-described methods for manufacturing the semiconductor lamination according to this invention, a semiconductor layer formed to have an amorphous area is used as the second semiconductor layer. As compared to a crystalline semiconductor layer, the semiconductor layer having the amorphous area has the advantage of being formed comparatively easily in a short time.

By any one of the above-described methods for manufacturing the semiconductor lamination according to this invention, a semiconductor layer exhibiting different melting behavior from that of the first semiconductor layer caused by light radiation is used as the second semiconductor layer.

The “different melting behavior” herein used means, for example, differences in a minimum melting temperature, viscosity in a melting state, and light energy or thermal energy required for melting. Accordingly, it is possible to selectively melt only either the first semiconductor layer or the second semiconductor layer.

By any one of the above-described methods for manufacturing the semiconductor lamination according to this invention, a semiconductor layer having a minimum melting temperature lower than a minimum melting temperature of the first semiconductor layer is used as the second semiconductor layer. Therefore, it is possible to melt only the second semiconductor layer.

By any one of the above-described methods for manufacturing the semiconductor lamination according to this invention, a semiconductor layer requiring lower light energy to melt than the light energy required to melt the first semiconductor layer is used as the second semiconductor layer. Therefore, it is possible to melt only the second semiconductor layer.

By any one of the above-described methods for manufacturing a semiconductor lamination according to this invention, a semiconductor layer of different composition from that of the first semiconductor layer is used as the second semiconductor layer. For example, the first semiconductor layer may be made of germanium and the second semiconductor layer may be made of silicon. In this case, since the first semiconductor layer and the second semiconductor layer have different substance parameters such as a bond length and a lattice constant, as a result of the structural change or crystallization of the second semiconductor layer, the crystal structure unique to silicon which constitutes the second semiconductor layer is easily influenced by germanium which constitutes the first semiconductor layer. This will be reflected in the properties of the second semiconductor layer.

By any one of the above-described methods for manufacturing a semiconductor lamination according to this invention, two materials selected from the group consisting of composite materials containing silicon and germanium separately, and both silicon and germanium are used as materials for the first semiconductor layer and the second semiconductor layer. Concerning all the above-mentioned three types of composite materials, their forming methods are established and they have structural parameters similar to each other. Accordingly, they have the advantage of comparatively easily forming a lamination before light radiation.

By any one of the above-described methods for manufacturing a semiconductor lamination according to this invention, a semiconductor layer having a film thickness of 100 nm or less is used as the second semiconductor layer. Accordingly, it becomes easy to cause photo excitation uniformly in the depth direction of the second semiconductor layer.

By any one of the above-described methods for manufacturing a semiconductor lamination according to this invention, light with a pulse width of 500 ns or less is used for the light radiation. Since the pulse width of the light used is sufficiently short, this method has the advantage of inhibiting thermal diffusion of the heat generated at the time of the light radiation toward the direction of the first semiconductor layer, and of making it possible to induce the structural change of only the second semiconductor layer.

By any one of the above-described methods for manufacturing a semiconductor lamination according to this invention, light with a wavelength of 600 nm or less is used for the light radiation. Accordingly, it is possible to efficiently cause light excitation of the second semiconductor layer.

A semiconductor device according to a third invention is manufactured by using a semiconductor lamination manufactured by any one of the above-described methods for manufacturing the semiconductor lamination. Since those methods for manufacturing the semiconductor lamination are intended to change the structural or electronic property unique to the material constituting the second semiconductor layer and, therefore, the semiconductor layer product manufactured thereby also turns out to exhibit excellent properties. Accordingly, the semiconductor device manufactured by using such a semiconductor lamination turns out to exhibit excellent device performance. Examples of this semiconductor device include transistors and diodes. The semiconductor lamination manufactured by any one of the above-described methods for manufacturing the semiconductor lamination may be utilized as-is to manufacture the semiconductor device, or additional processing may be applied to this semiconductor lamination to manufacture the semiconductor device. For example, the first semiconductor layer which is the base layer may be removed and only the second semiconductor layer may be utilized to manufacture the semiconductor device. A thin film transistor (TFT) manufactured by a thin film process is one example of such a semiconductor device.

Concerning the semiconductor device according to the third invention, at least a crystallized area in the second semiconductor layer of the semiconductor lamination manufactured by the method of manufacturing the semiconductor lamination according to the second invention is used as an active area of the semiconductor device. The substance structure of this crystallized area tends to become subject to perturbations by the structure or properties of the first semiconductor layer, and the crystallized area tends to obtain different structure and properties from those of the material constituting the second semiconductor layer. Accordingly, this semiconductor device can function as an excellent device. The term “active area” used in this specification means at least one portion or one area in which carriers flow. For example, if the semiconductor device is an MOS transistor, the active area indicates at least one area among a source area, a drain area, and a channel area.

Concerning the semiconductor device of this invention, a crystallized area formed by light radiation of a silicon layer formed as the second semiconductor layer over the first semiconductor layer made of a composite semiconductor material containing silicon and germanium is used as an active area of the semiconductor device. Because of a certain structural mismatch between the substance structure of the composite semiconductor containing silicon and germanium and the substance structure of the silicon, the lamination can be easily formed, and the crystallized area formed by the light radiation of the silicon layer tends to easily become subject to the perturbation of the first semiconductor layer. Accordingly, as compared to a conventional semiconductor device using a normal silicon in its active area, this semiconductor device can easily exhibit excellent performance.

Concerning the semiconductor device of this invention, the substance structure of the crystallized area is different from the substance structure unique to a silicon crystal. As compared to the silicon formed by a conventional method, this semiconductor device can easily exhibit excellent properties, for example, in terms of carrier mobility.

Concerning any one of the above-described semiconductor devices of this invention, the semiconductor device is a field-effect transistor. Accordingly, it is possible to realize an excellent field-effect transistor, for example, in terms of carrier mobility.

By a method for manufacturing a lamination according to a fourth invention, light radiation of a second substance layer formed over a first substance layer induces a structural change of the second substance layer. Examples of the second substance include oxides of a chalcogen group which is represented by selenium and tellurium. However, without limitation to such substances, this invention can be applied to any substance capable of crystallizing.

By the above-described method for manufacturing a lamination according to this invention, the structural change is influenced by the first substance layer. Accordingly, it is possible to form an area having a different structure from the structure unique to the second substance. This formed area can be used for various devices.

A method for manufacturing a semiconductor lamination according to a fifth invention comprises the steps of: forming, over a substrate, a first semiconductor layer including a first semiconductor alone, or both the first semiconductor and a second semiconductor; forming, over the first semiconductor layer, a second semiconductor layer made of the second semiconductor; and performing light radiation on a lamination made of the first semiconductor layer and the second semiconductor layer, thereby inducing a structural change.

The “structural change” herein used means, in addition to the aforementioned definition, changes in the bonding state of constituent atoms and also indicates, for example, changes in the crystal state such as crystallization of amorphous substances or recrystallization of polycrystal substances.

Concerning the above-described method for manufacturing the semiconductor lamination according to this invention, the first semiconductor is germanium.

Concerning the above-described method for manufacturing the semiconductor lamination according to this invention, the second semiconductor is silicon.

By any one of the above-described methods for manufacturing the semiconductor lamination according to this invention, the formation of the first semiconductor layer and the formation of the second semiconductor layer are conducted continuously in a vacuum.

Concerning any one of the above-described methods for manufacturing the semiconductor lamination according to this invention, the first semiconductor layer includes a crystalline area.

Concerning any one of the above-described methods for manufacturing the semiconductor lamination according to this invention, the first semiconductor layer is formed by crystallization caused by light radiation.

Concerning the above-described method for manufacturing the semiconductor lamination according to this invention, the first semiconductor layer is formed by crystallization caused by light radiation performed a plurality of times.

By the above-described method for manufacturing the semiconductor lamination according to this invention, the light radiation of the first semiconductor layer is performed in a vacuum.

By any one of the above-described methods for manufacturing the semiconductor lamination according to this invention, the light radiation of the lamination is conducted with strength of no less than an energy density capable of at least completely melting the second semiconductor layer.

Concerning any one of the above-described methods for manufacturing the semiconductor lamination according to this invention, the film thickness of the second semiconductor layer is 50 nm or less.

By any one of the above-described methods for manufacturing the semiconductor lamination according to this invention, the light radiation is conducted by using a pulse laser with a pulse width of 500 ns or less.

By any one of the above-described methods for manufacturing the semiconductor lamination according to this invention, the light radiation is conducted by using a pulse laser with a wavelength of 600 nm or less.

A sixth invention is a semiconductor device manufactured by any one of the methods for manufacturing the semiconductor lamination. The substance structure of the crystallized area of such semiconductor device tends to become subject to perturbations by the structure or properties of the first semiconductor layer, and the crystallized area tends to obtain a different structure and different properties from those of the material constituting the second semiconductor layer. Accordingly, this semiconductor device can function as an excellent device.

A seventh invention is electronic equipment comprising the semiconductor device of the sixth invention.

There is no limitation to the types of “electronic equipment,” but possible electronic equipment is that which comprises, for example, a display apparatus composed of the semiconductor device of this invention such as a TFT. Examples of such electronic equipment include cellular phones, video cameras, personal computers, head-mounted displays, rear or front projectors, facsimile devices having a display function, digital camera finders, portable televisions, DSP devices, PDAs, and electronic notepads.

### BRIEF DESCRIPTION OF THE DRAWINGS

FIG. 1 illustrates a semiconductor manufacturing method according to Embodiment 1 of the present invention.

FIG. 2 illustrates a method for manufacturing a field-effect transistor of Example 1 to which Embodiment 1 is applied.

FIG. 3 illustrates a semiconductor manufacturing method according to Embodiment 2 of this invention.

FIG. 4 illustrates a method for manufacturing a field-effect transistor of Example 2 to which Embodiment 2 is applied.

FIG. 5 is a connection diagram of a display panel according to Embodiment 3.

The drawings of FIG. 6 show examples of electronic equipment of Embodiment 3, which are sample applications of the display panel of this invention as applied to a cellular phone in FIG. 6(a), a video camera in FIG. 6(b), a portable personal computer in FIG. 6(c), a head-mounted display in FIG. 6(d), a rear projector in FIG. 6(e), and a front projector in FIG. 6(f).

FIG. 7 illustrates a crystal growing method of the background art.

### DETAILED DESCRIPTION OF THE PREFERRED EMBODIMENTS

Embodiments of this invention are hereinafter explained with reference to the attached drawings.

### Embodiment 1

Embodiment 1 of this invention relates to a method for manufacturing a lamination by performing light radiation on a second semiconductor layer formed over a first semiconductor layer, thereby inducing a structural change at least in a part of the second semiconductor layer.

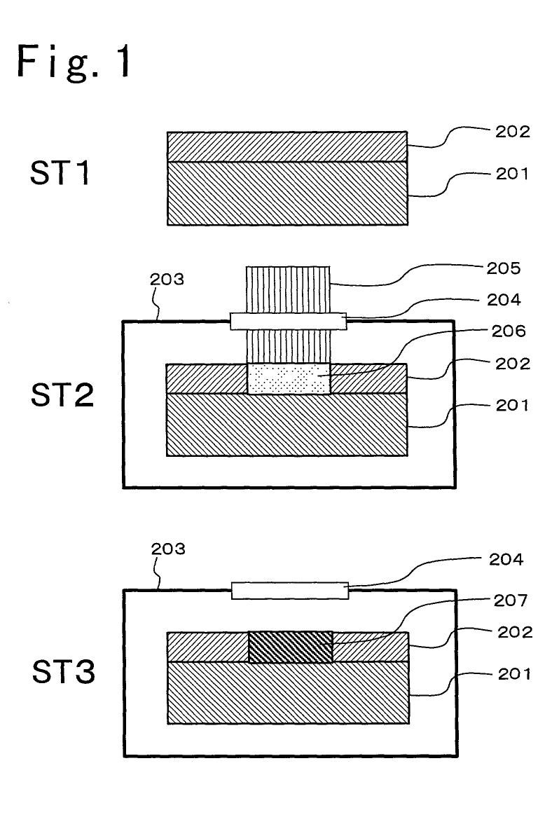

FIG. 1 shows sectional views illustrative of the manufacturing steps of the method for manufacturing the lamination of Embodiment 1.

As shown in FIG. 1 (ST1), a second semiconductor layer 202 is formed over a first semiconductor layer 201. Examples of semiconductors used for these first and second semiconductor layers include: semiconductor crystals made of only Group IVb elements such as silicon (Si) or germanium (Ge); composite semiconductor crystals containing Group IVb elements such as silicon germanium (SiₓGe₁₋ₓ: 0<x<1) crystal, silicon carbide (SiₓC₁₋ₓ: 0<x<1) crystal, or germanium carbide (GeₓC₁₋ₓ: 0<x<1) crystal; compound semiconductors of Group IIIb elements and Group Vb elements such as gallium arsenide (GaAs) or indium antimonide (InSb), or compound semiconductors of Group IIb elements and Group VIb elements such as cadmium selenide (CdSe); and multiple compound semiconductors such as silicon germanium gallium arsenide (Si_{w}GeₓGa_{y}As_{z}: w+x+y+z=1), as well as n-type semiconductors obtained by adding, to any of the multiple compound semiconductors, a donor element such as phosphorous (P), arsenic (As), or antimony (Sb), and p-type semiconductors obtained by adding, to any of the multiple compound semiconductors, an acceptor element such as boron (B), aluminum (Al), gallium (Ga), or indium (In). As for the materials used to compose the first and second semiconductor layers, it is possible to arbitrarily combine the above-mentioned materials.

It is desirable that the first semiconductor layer have a single-crystal structure. As this single-crystal structure, it is possible to use a single-crystal substrate itself or a single-crystal semiconductor formed by means of epitaxial growth over the single-crystal substrate. Considering costs for practical use, it is desirable that strain-relaxed silicon germanium which is caused to grow, by means of solid-phase epitaxial growth or molecular beam epitaxy, over a silicon substrate be used as the first semiconductor layer.

In this invention, it is desirable that a minimum melting temperature of the first semiconductor layer be higher than a minimum melting temperature of the second semiconductor layer. In order to set the melting temperatures in this manner, it is desirable that the first semiconductor layer with a composition ratio of silicon to germanium being, for example, 0.5:0.5, or with silicon contained at the rate of more than 0.5, be used in combination with amorphous silicon as the second semiconductor layer.

When the second semiconductor layer 202 is formed over the first semiconductor layer 201, the state of the interface will greatly influence the crystal growth. Accordingly, it is desirable for enhancement of yield of the device that pretreatment with acids, alkali solutions, or enzyme plasmas be given to metals or organic substances on the first semiconductor layer. Moreover, it is desirable that the second semiconductor layer 202 be formed immediately after the removal of a natural oxide film from the first semiconductor layer.

Examples of the method for forming the second semiconductor layer 202 over the first semiconductor layer 201 include: CVD (chemical vapor deposition) methods such as APCVD, LPCVD and PECVD methods; and PVD methods such as sputtering and evaporation.

When a silicon film is used as the second semiconductor layer 202, and if the LPCVD method is employed, it is possible to deposit the layer by setting a substrate temperature in the range of, for example, about 400° C. to about 700° C. and by using, for example, disilane (Si₂H₆) as a raw material. By the PECVD method, it is possible to deposit the layer by setting a substrate temperature in the range of, for example, about 100° C. to about 500° C. and by using, for example, mono-silane (SiH₄) as a raw material.

When the sputtering method is employed, the substrate temperature is in the range of room temperature to about 400° C. When the sputtering method is performed to deposit a semiconductor layer (for example, silicon germanium (SiₓGe₁₋ₓ: 0<x<1) containing two or more types of elements, such method is superior in that by using a raw material having a desired composition as a target, the formed semiconductor layer will have almost the same composition, and it is unnecessary to use noxious gas.

According to this invention, the initial state (or as-deposited state) of the second semiconductor layer 202 formed over the first semiconductor layer 201 maybe any of, for example, amorphous, mixed crystal, microcrystal, and polycrystal states. However, as stated above, in order to satisfy the condition that the second semiconductor layer should have a lower melting point than that of the first semiconductor layer, it is desirable that the initial state of the second semiconductor layer 202 be amorphous.

In this specification, the terms “crystal growth” and “crystallization” are used to indicate not only crystallization of amorphous substances, but they also include the recrystallization of polycrystal or microcrystal substances. There is no special limitation to the thickness of the second semiconductor layer, but it is desirable that the film thickness of the second semiconductor layer be 100 nm or less in order to satisfy both conditions that the entire layer can be melted by light radiation as described later, and that the strain crystal growth can be maintained. The surface of the semiconductor deposited by the CVD method such as the LPCVD method or the PECVD method, or by the sputtering method is often covered with a natural oxide film. Accordingly, it is desirable that this natural oxide film be removed. In order to do so, it is possible to adopt, for example, a method of performing wet etching by dipping the semiconductor layer in a fluoric acid solution, or a method of performing dry etching in a plasma containing a fluoric gas.

Subsequently, as shown in FIG. 1 (ST2), the substrate with the second semiconductor layer 202 formed therein is placed inside a light radiation vacuum chamber 203 having a quartz window 204. After the light radiation vacuum chamber 203 is evacuated to a vacuum, light 205 is radiated through this quartz window 204 to cause light crystallization of the second semiconductor layer 202. It is possible to reduce the amount of impurities to be mixed in the semiconductor layer from the atmosphere by means of evacuation at the time of the light crystallization. Particularly when it is intended to form a field-effect transistor, the surface of the second semiconductor layer 202, into which impurities may easily be mixed by means of the light radiation, forms the most important MOS interface. Therefore, it is desirable to inhibit the mixing of impurities in the semiconductor layer because this can control the device performance and variations therein.

A light source used for the light radiation is explained as follows: examples of the light source include a low-pressure mercury lamp, a high-pressure mercury lamp, an extra-high pressure mercury lamp, a zinc lamp, a halogen lamp, an excimer lamp, and a xenon lamp. It is also possible to use light which can be obtained by fundamental waves of the laser mentioned below or by non-linear optics effects of the fundamental waves of such laser, and examples of such laser include an excimer laser, an argon ion laser, akrypton ion laser, Nd:YVO₄ laser, Nd:YAG laser, Nd:YLF laser, Ti:sapphhire laser, a semiconductor laser, and a dye laser.

According to this invention, it is desirable that the radiated light be strongly absorbed by the semiconductor layer (particularly the second semiconductor layer 202). Accordingly, it is particularly desirable to use the light of higher harmonics such as the excimer laser, the argon ion laser, or the Nd:YAG laser which have wavelengths in an ultraviolet range or any other range in the vicinity thereof. Particularly if the film thickness of the second semiconductor layer is small, the excimer laser which has a short wavelength is suitable for the light source. On the other hand, if the film thickness is large, a second harmonic of the Nd:YAG laser which has a long wavelength is suitable for the light source. However, the laser light with wavelengths of approximately 600 nm or less satisfies the above-described condition.

A method for radiating the laser light is hereinafter explained. The laser light radiation is performed with the semiconductor layers 201 and 202 at a temperature, for example, in the range of room temperature (about 25° C.) to about 400° C., and in a vacuum with the degree of background vacuum in the range of about 10⁻⁴ Torr to 10⁻⁹ Torr. An irradiation area of one time laser radiation is set as, for example, a square or rectangle with the diagonal line length of about 5 mm to about 100 mm. As for the irradiation area, it is possible to control the size of the laser radiation area as appropriate by using an optical system utilizing, for example, a fly eye lens.

When the light is radiated on the second semiconductor layer by using a pulse laser, heat is generated by light energy absorbed in the light radiated area of the second semiconductor layer 202, thereby causing a rise in temperature in a very short time. A preferred pulse width of the laser is 500 ns or less. Since the then-generated heat diffuses, the second semiconductor layer is cooled down in a short time. When the light 205 has enough radiation energy to melt the second semiconductor layer, the second semiconductor layer forms a melted area 206 and crystallizes during the cooling process. If the radiation energy density is increased, the melted area 206 is formed even down to the deep part of the second semiconductor layer, which completely melts with energy exceeding a certain degree. If the energy density of the laser light is further increased, the first semiconductor layer also melts.

In other words, if the light radiation is conducted with the energy density that causes the second semiconductor layer to only partly melt, crystalline nuclei are generated or crystallization occurs with such nuclei at arbitrary positions in the second semiconductor layer, which accordingly tends to easily become polycrystallized. On the other hand, on the condition of the light radiation that causes the second semiconductor layer to completely melt and the first semiconductor layer not to melt, the second semiconductor layer in the melted state shows epitaxial growth with the nuclei of crystals of the first semiconductor layer. At this time, very high-speed crystal growth is achieved at a crystallization speed of 1 m/sec to 10 m/sec. The crystallization method of this invention is particularly superior to the conventional layer-by-layer crystallization in that strain crystals with little defects can be obtained at a high speed.

By moving the substrate relatively and by repeating the above-described light radiation, it is possible to form strain crystals in a short time over the entire large-area substrate region of 8 inches or larger. Moreover, since it is only required as much as possible to avoid the mixing of impurities into the surface of the second semiconductor layer, the degree of vacuum necessary for the crystal growth is merely about 10⁻⁶ Torr and it is possible to reduce manufacturing costs as much as possible without requiring an ultra-high-vacuum device as used in the conventional crystallization method. Furthermore, the crystallization method of this invention is characterized in that it is possible to dramatically increase a critical film thickness. For example, if the second semiconductor of 100% silicon is formed over strain-relaxed silicon germanium crystals with a mixing ratio of 0.5:0.5 and the light radiation is then performed by using a pulse laser, it is possible to realize strain silicon crystals which have shown epitaxial growth of 10 nm or more, which has been impossible in the conventional method. Because of a large lattice mismatch between the second semiconductor layer and the first semiconductor layer which is the base layer, the silicon crystals formed by the light radiation turn out to have intense lattice strains. Accordingly, it is possible to obtain a semiconductor having strong mobility enhancement, which has been impossible in the conventional method.

If such conditions are set that the energy density of the radiated light causes the second semiconductor layer to completely melt and the first semiconductor layer not to melt, it is possible to realize epitaxial crystallization of strain crystals as described above. The crystal growth starts from the solid state with regard to the first semiconductor layer and from the liquid state with regard to the second semiconductor layer, and the crystal growth terminates in a very short time on the order of 10⁻⁹ seconds. Accordingly, almost no exchange of atoms happens during the crystallization. In other words, almost no such mixing of the first semiconductor layer and the second semiconductor layer as is indicated as the problem in the related art happens at the interface between these layers. In order to realize the above-described conditions, it is desirable that the melting point of the second semiconductor layer be lower than the melting point of the first semiconductor layer. Even if the same material is used for both layers, its amorphous substance generally has a lower melting point than that of its crystal. Accordingly, strain crystallization can easily be realized by making the first semiconductor layer crystalline and the second semiconductor layer amorphous and by performing light radiation on these layers.

On the other hand, when the light of such energy density is radiated which can cause not only the second semiconductor layer, but also a part of the first semiconductor layer to melt, in addition to the second semiconductor layer, a melted area is also formed in the first semiconductor layer on the side facing the second semiconductor layer and the interface between the second semiconductor layer and the first semiconductor layer enters a melted state, thereby causing mutual diffusion. Crystallization starts from the melted area of the first semiconductor layer, which is followed by crystallization of the second semiconductor layer. The crystallization of the second semiconductor layer tends to be influenced by the first semiconductor layer, and strain crystals are thereby obtained.

As described above, by performing the light radiation with sufficient energy density to completely melt at least the second semiconductor layer, it is possible to form the strain crystals of good quality having a large area.

Since the strain semiconductor formed by the method of Embodiment 1 shows mobility enhancement, it has high current driving ability and exhibits excellent performance as a semiconductor device. Particularly, a field-effect transistor which uses strain silicon as an active layer or active area is important for practical use. This is because it is possible to form an insulated gate film with a low density of interface level by using a strain-relaxed silicon germanium crystal as the first semiconductor and silicon as the second semiconductor, and by oxidizing, by means of thermal oxidation which has been conventionally employed, strain silicon manufactured by the above-described crystallization method. When a field-effect transistor is manufactured by forming a gate electrode, a source electrode, and a drain electrode, it is possible to realize the transistor with mobility twice as high as a conventional transistor. In the present semiconductor industry, the device size is 1 μm or less and the wiring capacity determines the speed of a circuit. Under the circumstances, by using the strain silicon which is disclosed in this invention and has high current driving ability, it is possible to easily realize the enhancement of performance, which corresponds to microfabrication technique development for two generations, without changing design rules.

### EXAMPLE 1

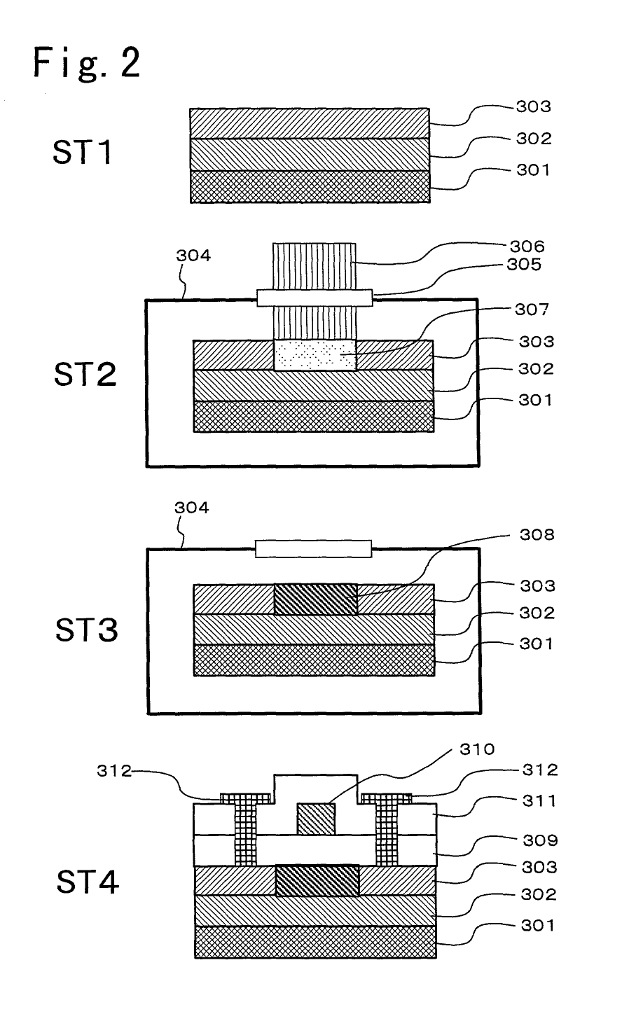

Example 1 according to Embodiment 1 is hereinafter explained with reference to FIG. 2.

First as shown in FIG. 2 (ST1), as an example of the substrate, a silicon substrate 301 was used which was a round p-type silicon with a diameter of 8 inches, 100 surface orientation, and 3 to 5 Ωcm resistivity. This silicon substrate was cleaned by means of RCA cleaning and hydrogen termination was conducted to adjust and make the surface of the substrate stable. Subsequently, this substrate was kept in a vacuum container and a silicon germanium film 302 (Si_{0.7}Ge_{0.3} with a film thickness of 250 nm) used as the first semiconductor layer was formed by molecular beam epitaxy at a substrate temperature of 100° C. Since the above-mentioned film thickness was more than a critical film thickness, stress relaxation occurred in the vicinity of the substrate, thereby forming a strain-relaxed silicon germanium crystal. Then, an amorphous silicon film 303 with a thickness of 50 nm was formed over the above-obtained first semiconductor layer by means of low pressure CVD (LPCVD). In this example, a high vacuum LPCVD device was used to send in 200 SCCM disilane (Si₂H₆) as a raw material gas and to deposit the amorphous silicon film 303 at a deposition temperature of 425° C. First, as the temperature of a reaction chamber was set at 250° C., a plurality of substrates (for example, 17 sheets) with their front sides facing downward were placed inside the reaction chamber. A turbo-molecular pump was then turned on. After the turbo-molecular pump reached the state of steady rotations, the temperature inside the reaction chamber was increased from 250° C. to the deposition temperature of 425° C. in about one hour. For the first ten minutes immediately after starting to increase the temperature, such increase in temperature was conducted in a vacuum without introducing any gas. Then, a 300 SCCM nitrogen gas at a purity greater than 99.9999% was continuously provided. A pressure balance inside the reaction chamber at that time was 3.0×10⁻³ Torr. After the deposition temperature was achieved, 200 SCCM disilane (Si₂H₆) as a raw material gas was supplied as well as 1000 SCCM helium (He) for dilution purposes at a purity greater than 99.9999%. The pressure within the reaction chamber immediately after the start of deposition was about 0.85 Torr. The pressure within the reaction chamber gradually increased along with the progress of deposition, and the pressure immediately before the termination of deposition was about 1.25 Torr. Variations in the film thickness of the deposited silicon film 303 were in the range of ±5% in the area of the 8-inch substrate excluding an approximately 7 mm peripheral part of the substrate.

As shown in FIG. 2 (ST2), this substrate was then set in a light radiation vacuum chamber 304, which was evacuated to a vacuum to approximately 10⁻⁷ Torr. Light 306 was radiated through a quartz window 305 by using a XeCl excimer laser with a wavelength of 308 nm. The pulse width of the used laser light was 25 ns, and the light was reshaped to a top flat beam with intensity distribution of 5% or less and with a beam size of 10 mm×10 mm square on a sample surface and was radiated through an optical system using a fly eye lens. An energy density was set to 450 mJ/cm² and the light of one pulse was radiated per one position. The radiated area was of the size corresponding to one chip of the device. The one-pulse light with the beam size of 10 mm×10 mm was radiated on the places corresponding to the respective chip positions and the light radiation was performed on the entire 8-inch substrate while moving the substrate. Accordingly, a melted area 307 was formed in each 10 mm×10 mm area on which the light radiation was performed. Subsequently, as shown in FIG. 2 (ST3), a strain silicon crystal area 308 was successfully formed on the strain-relaxed silicon germanium crystals.

The furnace temperature was then increased at the rate of 10° C. per minute. After the furnace temperature reached 1160° C., thermal oxidation was performed for 10 minutes at this temperature. Subsequently, while the temperature was maintained at 1160° C., the gas was changed to nitrogen and further thermal treatment was performed for 15 minutes. The temperature was then decreased at the rate of 5° C. per minute. When the temperature went down to 800° C., the substrate was taken out. A gate oxide film 309 obtained in this matter had a film thickness of 60 nm and exhibited very good interface properties with an interface level density of 10¹⁰ cm⁻².

Subsequently, as shown in FIG. 2 (ST4), a gate electrode 310 was formed by using polycrystal silicon, and an interlayer insulation film 311 was formed by plasma CVD by means of TEOS and oxygen mixing. After contact holes were opened, source and drain electrodes 312 were formed, thereby completing a field-effect transistor.

The field-effect transistor manufactured in the above-described manner exhibited the field-effect mobility twice as high as a conventional case in which the strain silicon was not used. This advantageous effect was achieved only by using the strain silicon manufactured by the very high-speed crystal growth by using the laser light radiation as disclosed in this invention.

### Embodiment 2

Embodiment 2 of this invention relates to a method for manufacturing a lamination, comprising the step of performing light radiation not only on a second semiconductor layer as a top layer of the lamination as in Embodiment 1, but also on the lamination consisting of the first semiconductor layer and the second semiconductor layer.

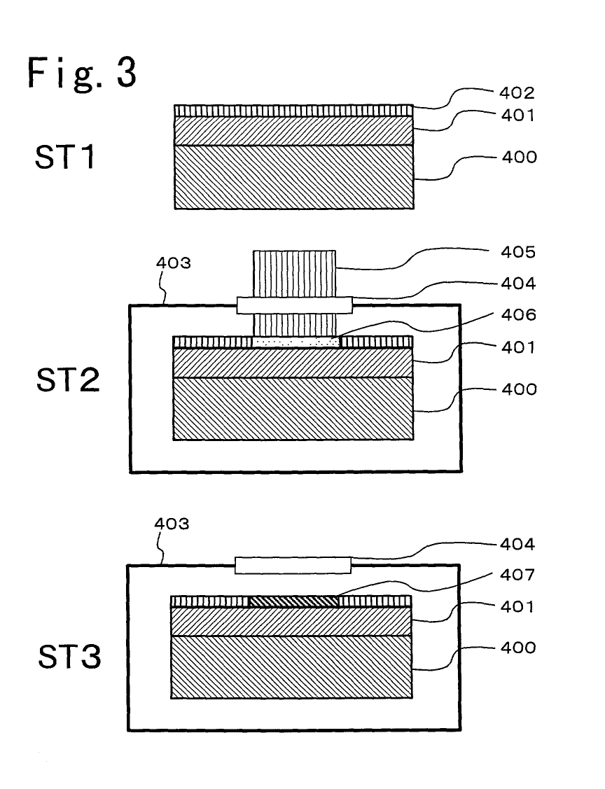

FIG. 3 shows sectional views illustrative of the manufacturing steps of the method for manufacturing the lamination according to Embodiment 3.

In order to carry out this invention, as shown in FIG. 3 (ST1), a first semiconductor layer 401 is formed over a substrate 400, and a second semiconductor layer 402 is further formed over the first semiconductor layer 402. Examples of the substrate 400 to which this invention can be applied include: conductive substances such as metals; ceramic materials such as silicon carbide (SiC), alumina (Al₂O₃), and aluminum nitride (AlN); transparent or opaque insulating substances such as molten quartz or glass; and semiconductor substances such as silicon wafers, and LSI substrates made by processing such semiconductor substances. It is also possible to use, as the substrate, polymers such as PES or PET.

FIG. 3 (ST1) illustrates the case in which the semiconductor layers 401 and 402 are formed directly on the substrate. The semiconductor layers 401 and 402 are deposited directly or through, for example, a base protection film or a lower electrode, on the substrate. However, when the semiconductor layers are formed on a glass or polymer substrate, the base protection film is required. When the base protection film is formed, an insulating substance such as silicon oxide (SiOₓ: 0<x≦2) or silicon nitride (Si₃Nₓ: 0<x≦4) is used. When a thin film semiconductor device such as a thin film transistor (TFT) is formed on a normal glass or polymer substrate, it is important to control the mixing of impurities into the semiconductor films. In this case, it is desirable that the semiconductor films be deposited after the base protection film is formed in such a manner that movable ions of, for example, sodium (Na) contained in the glass substrate or polymer substrate are not mixed into the semiconductor films. The same rule can be applied to the case in which various kinds of ceramic materials are used for the substrate. The base protection film prevents impurities such as sintering auxiliary agent raw materials added in the ceramics from diffusing and mixing into the semiconductor parts. When a conductive material such as a metallic material is used as the substrate and the semiconductor films have to be electrically isolated from the metallic material, the base protection film is absolutely necessary in order to secure insulation. Moreover, when the semiconductor films are formed on the semiconductor substrate or an LSI device, an interlayer insulation film between transistors or wirings also serves as the base protection film.

After the substrate is cleaned with pure water or an organic solvent such as alcohol, the base protection film is formed by a CVD method, such as atmospheric pressure chemical vapor deposition (APCVD), low pressure chemical vapor deposition (LPCVD), or plasma-enhanced chemical vapor deposition (PECVD), or a sputtering method.

When a silicon oxide film is used as the base protection film, deposition can be performed by the atmospheric pressure chemical vapor deposition at a substrate temperature in the range of about 250° C. to about 450° C. by using mono-silane (SiH₄) and oxygen as raw materials.

By the plasma-enhanced chemical vapor deposition or the sputtering, the substrate temperature is in the range of room temperature to about 400° C. The base protection film needs enough film thickness to prevent impurity elements from the substrate from diffusing and mixing into the semiconductor layers, and a minimum film thickness is about 100 nm or more. Considering variations between lots or substrates, a preferred film thickness is about 200 nm or more. If the film thickness is about 300 nm, the film can fully perform its functions as the protection film. If the base protection film also serves as an interlayer insulation film, for example, between IC devices or in wiring to couple such IC devices, the film thickness is normally in the range of about 400 nm to about 600 nm. If the insulation film is too thick, cracks will be generated due to stress on the insulation film. Accordingly, a maximum film thickness of the insulation film is preferably about 2 μm. If it is very necessary to consider the productivity, it is desirable that the film thickness of the insulation film be about 1 μm or less.

Subsequently, the first semiconductor layer 401 is formed over the above-described substrate 400. This semiconductor layer is made of a first semiconductor alone, or both the first semiconductor and a second semiconductor. Examples of the first and second semiconductors to which the present invention can be adapted include: element semiconductors of only Group IVb elements such as silicon (Si) or germanium (Ge); composite semiconductors containing Group IVb elements such as silicon germanium (SiₓGe₁₋ₓ: 0<x<1), silicon carbide (SiₓC₁₋ₓ: 0<x<1), or germanium carbide (GeₓC₁₋ₓ: 0<x<1); and composite compound semiconductors of Group IIIb elements and Group Vb elements such as gallium arsenide (GaAs) or indium antimonide (InSb), or composite compound semiconductors of Group IIb elements and Group VIb elements such as cadmium selenide (CdSe) . It is also possible to adapt this invention to further composite compound semiconductors such as silicon germanium gallium arsenide (Si_{w}GeₓGa_{y}As_{z}: w+x+y+z=1), as well as n-type semiconductors obtained by adding, to any of the further composite compound semiconductors, a donor element such as phosphorous (P), arsenic (As), or antimony (Sb), and p-type semiconductors obtained by adding, to any of the further composite compound semiconductors, an acceptor element such as boron (B), aluminum (Al), gallium (Ga), or indium (In). As for the materials to compose the first and second semiconductors, it is possible to arbitrarily combine the above-mentioned materials.

However, considering easy handling and lattice matching, silicon and germanium are the most suitable materials. Both pure silicon and germanium crystals are of a diamond structure and have a 4.2% lattice mismatch. These materials have the advantage of being capable of controlling the lattice constant of their mixture by changing their mixing ratio to form crystals from the mixture of silicon and germanium. Specifically, when germanium is used as the first semiconductor and silicon is used as the second semiconductor, and if they are mixed at the rate of 50% respectively, it is possible to produce crystals having a lattice constant which is exactly an intermediate value between the lattice constant of the pure silicon and the lattice constant of the pure germanium. Since they are 100% soluble, they have the advantage of not causing segregation at the time of crystallization by a thermal action utilizing light radiation as described later. Because of the above-described reasons, silicon and germanium are well suited for the first and second semiconductors. It is certainly possible to use a simple substance of germanium as the first semiconductor layer.

Examples of the film forming method which can be applied to the formation of the first semiconductor layer of Embodiment 2 include: a CVD method such as atmospheric pressure chemical vapor deposition (APCVD), low pressure chemical vapor deposition (LPCVD), plasma-enhanced chemical vapor deposition (PECVD), or ultra-high vacuum CVD; a sputtering method; or a vacuum evaporation method such as electron beam evaporation.

By the CVD method, it is possible to form films by using SiH₄ or GeH₄ gas as a raw material. By the sputtering method or the evaporation method, it is possible to use a solid target such as Si or Ge as a raw material. In the case of the sputtering method, when a semiconductor used to deposit is a mixture of two or more kinds of materials (such as silicon germanium SiₓGe₁₋ₓ: 0<x<1), if a substance of such composition is used as a target, such method is superior in that the composition of the formed semiconductor will become almost the same and it is unnecessary to use a noxious gas.

It is desirable that the first semiconductor layer of this invention has a crystalline area. This is because it is necessary to produce strains in the second semiconductor layer due to the lattice mismatch as described later. Accordingly, when the above-described semiconductor layer forming method is employed, it is necessary to increase the substrate temperature at least to 600° C. or higher at the time of film formation. Therefore, such method is not suited for an inexpensive glass or polymer substrate. A further effective method is to form the first semiconductor layer on the substrate at a low temperature and then to make the first semiconductor layer polycrystalline by means of light radiation. The first semiconductor layer formed at a low temperature becomes amorphous in most cases. Such first semiconductor layer can be made polycrystalline in a very short time by radiating, for example, a pulse laser on it. By this method, the method for manufacturing a thin film semiconductor according to the present invention can be applied also to the glass or polymer substrate by using the base protection film.

It is desirable that the above-mentioned light radiation be performed in a vacuum for the purposes of avoiding the mixing of impurities into the first semiconductor layer and of keeping the interface clean between the first semiconductor layer and the second semiconductor layer to be formed subsequently. Particularly, if impurities exist in the interface between the second semiconductor layer and the first semiconductor layer, such existence may cause the generation of crystal defects (such as stacking faults or transformation) at the time of strain crystal growth of the second semiconductor layer, thereby considerably damaging the crystalline property of the second semiconductor layer.

The second semiconductor layer 402 is then formed over the first semiconductor layer 401. When the first semiconductor layer is formed and is then exposed to the atmosphere, it is important to remove metals or organic substances on the first semiconductor layer 401 by using an alkali solution or to ash them with an oxygen plasma. Moreover, it is necessary to remove the natural oxide film from the first semiconductor layer 401 immediately before the formation of the second semiconductor layer 402. Furthermore, it is desirable that continuously after the formation of the first semiconductor layer as described above, the second semiconductor layer be formed in a vacuum. As materials for the second semiconductor layer, any material having a different lattice constant from that of the semiconductor constituting the first semiconductor layer can be applied. However, when a single substance of germanium or a mixture of germanium and silicon is used for the first semiconductor layer, silicon is suited for the second semiconductor layer. This is because such selection of the material is appropriate for the crystal growth caused by the influence of the strains of the first semiconductor layer in the later step of crystal growth by light radiation, and because when it is intended to apply the thin film semiconductor of this invention to a field-effect transistor, it is possible to form a good interface with a low trap level by using SiO₂ for the gate insulation film.

The second semiconductor layer 402 can be formed, for example, by the CVD method such as APCVD, LPCVD, or PECVD, or by the sputtering method, or by the evaporation method. When, for example, a silicon film is used as the second semiconductor layer 402, the layer can be deposited by the LPCVD method by using, for example, disilane (Si₂H₆) as a raw material and by setting the substrate temperature in the range of about 400° C. to about 700° C. By the PECVD method, the layer can be deposited by using, for example, disilane (Si₂H₆) as a raw material and by setting the substrate temperature in the range of about 100° C. to about 500° C. When the sputtering method is employed, the substrate temperature is in the range of room temperature to about 400° C.

The initial state (as-deposited state) of the semiconductor deposited in the above-described manner can be in any of various states such as amorphous, mixed crystal, microcrystalline, and polycrystalline states. In the present invention, the initial state may be any of the above-mentioned states. In this specification, the terms “crystal growth” and “crystallization” include not only the crystallization of amorphous substances, but also the recrystallization of polycrystalline or microcrystalline substances.

The film thickness of the second semiconductor is determined by satisfying the conditions that the film thickness should be sufficient to enable the melting of the entire film by the following light radiation, and that the film thickness should make it possible to maintain the strain crystal growth. Accordingly, a film thinner than at least 100 nm is preferred. The film thickness of 50 nm or less is more preferred.

When, for example, silicon germanium is used for the first semiconductor layer and silicon for the second semiconductor layer, the second semiconductor layer has a higher melting point. However, in order to cause the strain crystal growth of the second semiconductor layer, it is necessary to cause the crystal growth from the first semiconductor layer in an epitaxial manner. Accordingly, it is necessary to perform heat crystallization treatment in a very short time by means of light radiation using a pulse laser, and to require a comparatively thin film thickness of the second semiconductor layer 402. In other words, the light radiation causes the temperature of the first semiconductor layer 401 and the second semiconductor layer 402 to rise and then causes these layers to melt. When oscillation of the pulse laser terminates, the temperature of the semiconductor layers decreases sharply at a high cooling rate of about 10¹⁰ K/s due to the thermal diffusion to the substrate. In some case, the semiconductor layers 401 and 402 enter a super cooled state. However, once the crystal growth starts, latent heat generates, thereby causing the temperature of the second semiconductor layer 402 to increase close to its melting point.

If the film thickness of the second semiconductor layer 402 is sufficiently thin at that time, the total amount of the generated latent heat is small and the crystal growth advances gradually from the first semiconductor layer 401 (that is, from the lower part of the second semiconductor layer) toward the direction of the surface of the second semiconductor layer. As a result, the second semiconductor layer 402 crystallizes, influenced by the lattice constant of the first semiconductor layer 401. Accordingly, it is possible to produce strong strains in the second semiconductor layer 402.

On the other hand, if the film thickness of the second semiconductor layer 402 is thick, the generated latent heat causes the first semiconductor layer 401 to melt again. As a result, crystal nuclei are randomly generated in the second semiconductor layer 402 in the liquid state, which then starts the crystal growth. As a result, this hinders the epitaxial strain crystal growth from the first semiconductor layer 401.

As described above, the rapid cooling of the semiconductor layers and the thermal diffusion to the substrate are important for the strain crystal growth. Therefore, the desirable film thickness of the second semiconductor layer 402 is approximately 50 nm or less and the desirable oscillation time of the radiating pulse laser is approximately 500 ns or less.

After the second semiconductor layer 402 is formed over the first semiconductor layer in the above-described manner, as shown in FIG. 3 (ST2), the light radiation is performed on this lamination, thereby causing crystallization. Specifically, the substrate with the first semiconductor layer 401 and the second semiconductor layer 402 placed thereon is set in a laser radiation chamber 403. A part of the laser radiation chamber is composed of a quartz window 404. After the chamber is evacuated to a vacuum, a laser light 405 is radiated through this quartz window. The evacuation can dramatically reduce the amount of impurities mixed from the atmosphere into the semiconductor in which the crystal growth has been caused by the laser radiation. Particularly if the formation of the field-effect transistor is considered, since the surface of the second semiconductor layer 402, into which impurities can be easily mixed by means of the laser radiation, forms an important MOS interface, it is important to inhibit the mixing of impurities in controlling the device performance and variations.

The following provides explanations about the laser light. It is desirable that the laser light be strongly absorbed by the semiconductor layers 401 and 402. Accordingly, preferred examples of the laser light include an excimer laser, an argon ion laser, and a YAG laser harmonic which have wavelengths in an ultraviolet range or any other range in the vicinity thereof. Particularly if the film thickness of the second semiconductor layer is small, the excimer laser which has a short wavelength is preferred. On the other hand, if the second semiconductor layer is comparatively thick, the YAG laser harmonic is suitable, but any laser having a wavelength of approximately 600 nm or less is appropriate because it can satisfy the above-described condition comparatively easily. The selection of the radiation laser is very important in precisely controlling the melting depth of the second semiconductor layer 402. Moreover, pulse oscillation of large output in a very short time is required in order to heat the second semiconductor layer 402 or the first semiconductor layer 401 to high temperatures and to precisely control the melting depth at the same time. Among the above-mentioned laser lights, the most suitable pulse oscillation is that of the excimer laser such as a xenon chloride (XeCl) laser (wavelength: 308 nm) or krypton fluoride (KrF) laser (wavelength: 248 nm), or that of the YAG laser harmonic.

The following provides explanations about the method for radiating the laser light. As for the half-width of the laser pulse intensity, the appropriate time value is 500 ns or less as described above. The laser radiation is performed by setting the temperature of the semiconductor layers 401 and 402 in the range of room temperature (about 25° C.) to about 400° C., and in a vacuum with the degree of background vacuum in the range of about 10⁻⁴ Torr to 10⁻⁹ Torr. An irradiation area of one-time laser radiation is a square or rectangle with the diagonal line length of about 5 mm to about 100 mm. The irradiation area can be decided corresponding to the formed area of the semiconductor device or any circuit formed by using such semiconductor device. It is possible to control the size of the laser radiation area as appropriate by using an optical system utilizing, for example, a fly eye lens.

When the pulse laser radiation is performed on the semiconductors on the above-described conditions, the absorbed light energy is converted into thermal energy in the vicinity of the surface of the second semiconductor layer, thereby increasing the temperature of the area in a very short time. Since the heat then diffuses to the first semiconductor layer 401 and the substrate, the second semiconductor layer 402 is cooled down sharply. When the energy density of the radiating pulse laser 405 reaches a sufficient value to melt the second semiconductor layer 402, the second semiconductor layer 402 forms a melted area 406 and crystallizes in the cooling step. As the radiation energy density is further increased, the second semiconductor melts in its deeper part and then completely melts with energy exceeding a certain degree. If the energy density is further increased, the first semiconductor layer also starts melting.

In the crystal growth realized by such pulse laser radiation, the crystal state of the second semiconductor layer 402 changes greatly depending on to how much depth it has melted. In other words, in the case of the laser radiation with such energy density as causes the second semiconductor layer 402 to melt only partly, crystal nuclei are generated at arbitrary positions in the second semiconductor layer 402 and the crystal grow with such nuclei takes place, thereby making the second semiconductor layer 402 microcrystalline. However, in the laser radiation condition that enables the second semiconductor layer 402 to melt completely and the first semiconductor layer 401 to melt only slightly, the second semiconductor layer 402 shows the epitaxial growth with nuclei of polycrystalline crystal grains of the first semiconductor layer 401. The crystal growth speed at this time reaches 1 to 10 m/sec, that is, very high speed crystal growth.

The crystal growth method of the present invention is particularly superior in that the strain crystal growth can be realized with almost no defect in the crystal grains on the above-described conditions. Concerning the conventional layer-by-layer crystal growth, the crystal growth is performed at very low speeds to realize the strain crystal growth without producing crystal defects. However, in the present invention, the crystal defects do not form until more than the specified period of time has passed during the crystal growth.

On the contrary, in the very high-speed crystal growth at a speed exceeding 1 m/sec such as the crystal growth induced by the pulse laser radiation, the crystal growth speed is considerably faster than the time required to produce crystal defects. As shown in FIG. 3 (ST3), it is possible to realize excellent strain crystals with very few crystal defects in the crystal grains of the second semiconductor polycrystals 407 obtained by the epitaxial growth. Moreover, since the crystal growth method of this invention can be realized by one shot of the laser radiation, it is possible to form the strain polycrystals in an extremely short time, that is, 1 sec or shorter for an area having a side of 10 mm or more.

By moving the substrate relatively to the laser light and by repeating the light radiation, it is possible to form the strain polycrystals in a short time over the entire large-area substrate region having a side of 50 cm or more.

Moreover, since it is only necessary to avoid the mixing of impurities into the surface of the second semiconductor layer 402 as much as possible, the degree of vacuum necessary for the crystal growth is merely about 10⁻⁶ Torr and it is possible to reduce costs for manufacturing apparatuses as much as possible without requiring an ultra-high-vacuum device as used in the conventional method.

Moreover, since the strain polycrystal growing method disclosed in this invention can be conducted at a process temperature of 200° C. or less, it is possible to realize, over a glass or polymer substrate, a high-quality polycrystal semiconductor film exhibiting strong mobility enhancement, which has been impossible to realize by the conventional method.

### EXAMPLE 2

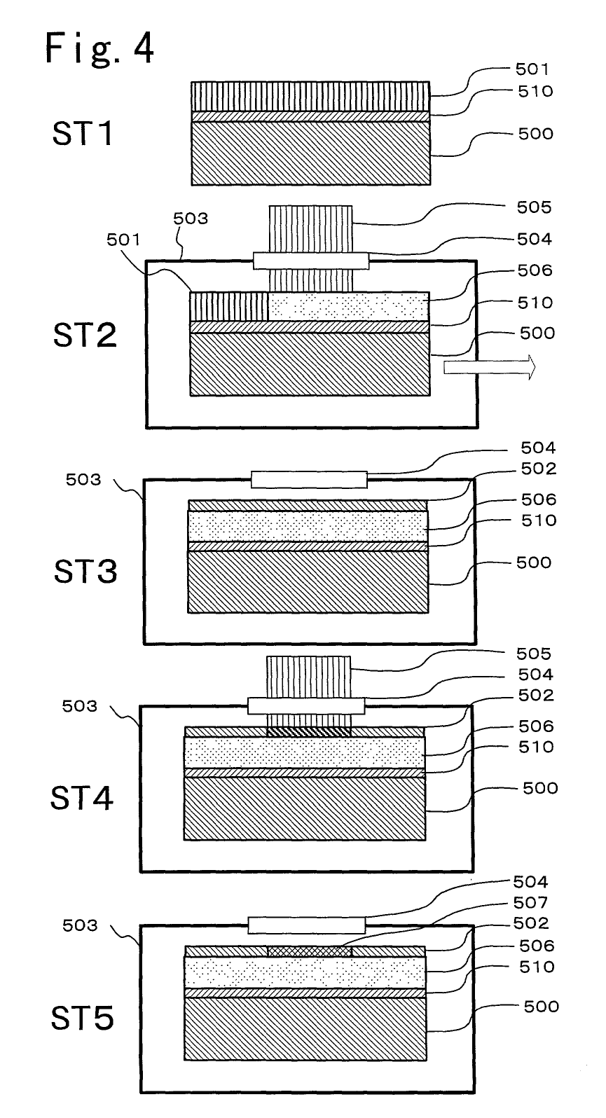

Example 2 according to Embodiment 2 of this invention is hereinafter explained with reference to FIG. 4. In Example 2, 30 mm×30 mm no-alkali glass 500 was used as an example of the substrate.

First as shown in FIG. 4 (ST1), this substrate was placed in a vacuum container, and a SiO₂ film with a film thickness of 200 nm to serve as a base protection film was formed by plasma CVD at a substrate temperature of 100° C. Then, silicon germanium (Si_{0.7}Ge_{0.3}) 501 to serve as the first semiconductor layer was formed by a sputtering method. A silicon germanium mixture of the above-mentioned composition was previously used as a target, and argon was used as a sputtering gas. The substrate temperature was 100° C. at the time of film formation and the formed film was amorphous.

As shown in FIG. 4 (ST2), after the first semiconductor layer 501 was formed, the substrate was moved by vacuum conveyance to a laser radiation chamber 503, which was evacuated to a vacuum to approximately 10⁻⁷ Torr. A XeCl excimer laser light 505 with a wavelength of 308 nm was then radiated through a quartz window 305. The pulse width of the used laser was 50 ns, and the light was reshaped to a top flat beam with intensity distribution of 5% or less and with a beam size of 10 mm×10 mm square on a sample surface and was radiated through an optical system using a fly eye lens. It was unnecessary to heat the substrate at the time of radiation of the excimer laser, but treatment was performed at a substrate temperature of 100° C. in order to enhance throughput of the continuous process in a vacuum. The excimer laser radiation started from an energy density of 160 mJ/cm², and the energy was gradually increased to the energy of 400 mJ/cm², during which about 20-shot radiation was performed. In order to make the first semiconductor layer polycrystalline on the entire surface of the substrate, the laser radiation was performed while scanning the substrate. The substrate was scanned in such a manner that the laser beams of the respective shots were radiated in the X and Y directions so that they would overlap one another by 75%. Accordingly, a first semiconductor layer 506 which has been thereby polycrystallized was formed.

As shown in FIG. 4 (ST3), after the polycrystalline silicon germanium semiconductor layer was formed in a vacuum, the substrate was carried in a vacuum to form a second semiconductor layer 502. An amorphous silicon film 502 with a film thickness of 50 nm was formed by sputtering over the first semiconductor layer 501. Film forming conditions were the same as those for forming the first semiconductor layer 501 before crystallization, except that only silicon was used as a target.

Subsequently, as shown in FIG. 4 (ST4), after the first semiconductor layer 501 and the second semiconductor layer 502 were formed, the obtained lamination was carried in a vacuum to perform the excimer laser radiation 505 again. The excimer laser radiation was conducted on almost the same conditions as those of the laser radiation on the first semiconductor layer as described above. However, in order to precisely control the melting depth of the semiconductor layers, only one-shot radiation was performed with an energy density of 240 mJ/cm².

Accordingly, as shown in FIG. 4 (ST5), a strain polycrystal silicon film 507 influenced by the lattice constant of the first polycrystal silicon germanium was successfully formed in the second semiconductor layer. This strain polycrystal silicon film can be formed to have a large area by scanning the substrate with the laser light.

### Embodiment 3

Embodiment 3 relates to a display device which utilizes a semiconductor device, particularly a TFT, manufactured by the manufacturing methods explained in the above-described embodiments, and to electronic equipment comprising such display device.

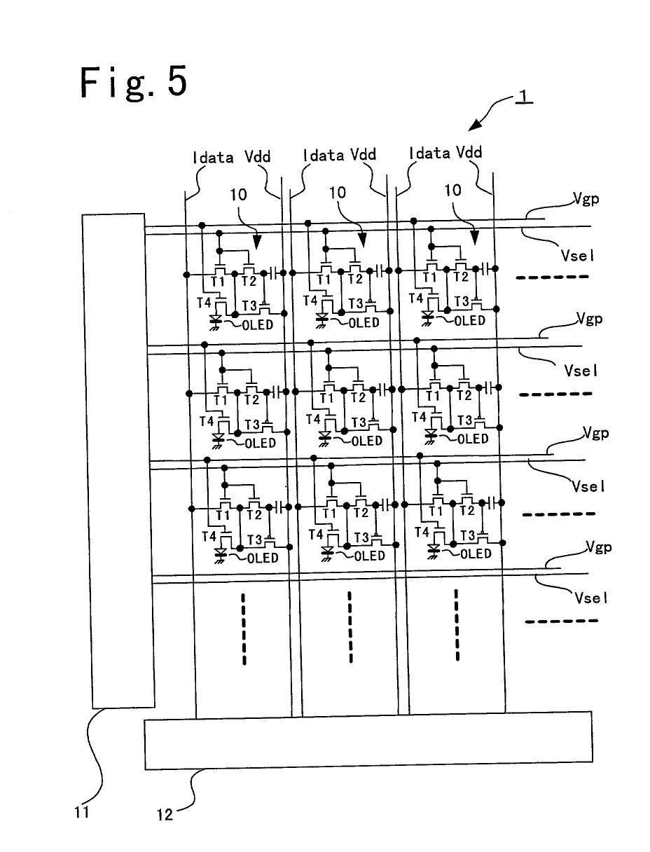

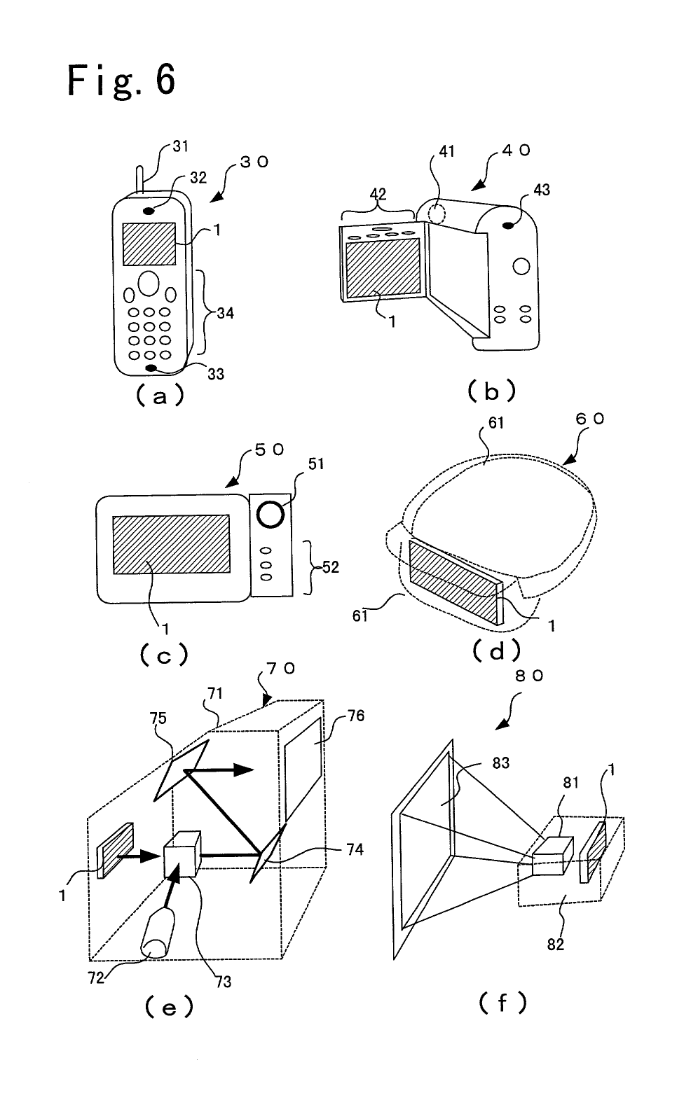

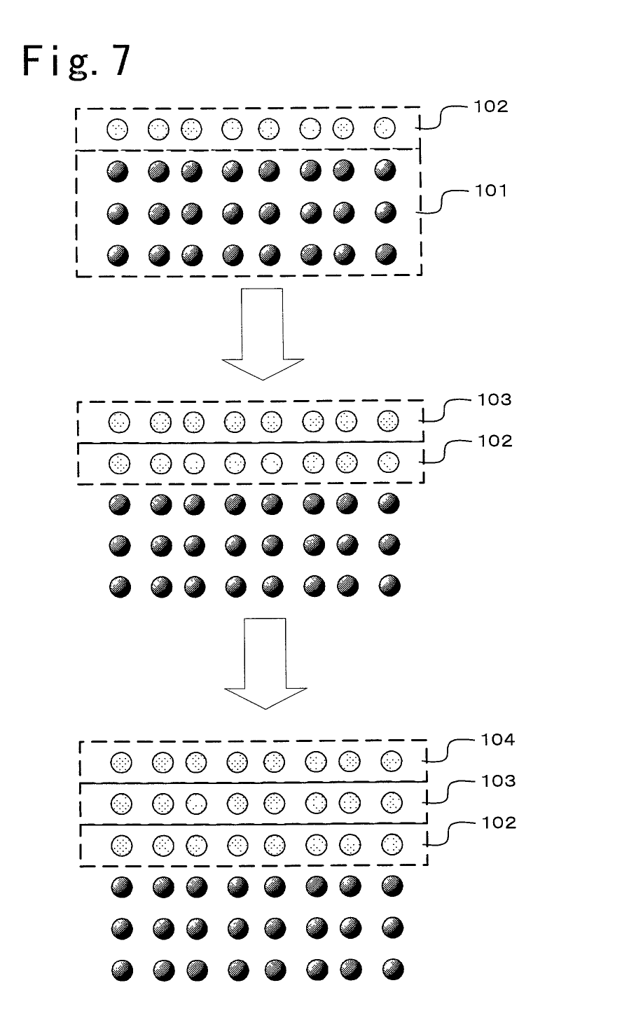

FIG. 5 shows a connection diagram of a display panel 1 of Embodiment 3. The display panel 1 is composed by arranging picture elements 10 in a matrix in a display area. In each picture element area 10, a peripheral circuit is formed for driving a light emitting part (OLED) which serves as a light emitting element. Active devices (TFTs) T1 through T4 which compose this peripheral circuit are the semiconductor devices manufactured by the manufacturing method of this invention.

Driver areas 11 and 12 drive the TFTs in each picture element area 10. Light emitting control lines Vgp and write control lines Vsel are supplied from the driver area 11 to the respective picture element areas. Constant current lines Idata and power source lines Vdd are supplied from the driver area 12 to the respective picture element areas. The write control lines Vsel and the constant current lines Idata are controlled to run a current program for each picture element area 10, and the light emitting control lines Vgp are controlled to control light emission at the light emitting part (OLED) in each picture element area.

The circuit structure of the display panel of Embodiment 3 is one example. The semiconductor device manufactured by the manufacturing method of this invention can be applied to various circuits.

The following examples are electronic equipment to which the display panel manufactured in the above-described manner can be applied.

FIG. 6(a) is an example of application to a cellular phone. A cellular phone 30 comprises an antenna 31, a voice output part 32, a voice input part 33, an operation part 32, and the display panel 1 of this invention. In this way, the display panel of this invention can be utilized as a display part.

FIG. 6(b) is an example of application to a video camera. A video camera 40 comprises an image receiving part 41, an operation part 42, a voice input part 43, and the display panel 1 of this invention. In this way, the display panel of this invention can be utilized as a finder or a display part.

FIG. 6(c) is an example of application to a portable personal computer. A computer 50 comprises a camera part 51, an operation part 52, and the display panel 1 of this invention. In this way, the display panel of this invention can be utilized as a display part.

FIG. 6(d) is an example of application to a head-mounted display. A head-mounted display 60 comprises a band 61, an optical system receiving part 62, and the display panel 1 of this invention. In this way, the display panel of this invention can be utilized as a picture image display source.

FIG. 6(e) is an example of application to a rear projector. A rear projector 70 comprises a housing 71, a light source 72, a composite optical system 73, a mirror 74, a mirror 75, a screen 76, and the display panel 1 of this invention. In this way, the display panel of this invention can be utilized as a picture image display source.

FIG. 6(f) is an example of application to a front projector. Concerning a front projector 80, a housing 82 comprises an optical system 81 and the display panel 1 of this invention to enable the display of picture images on a screen 83. In this way, the display panel of this invention can be utilized as a picture image display source.

Without limitation to the above examples, the semiconductor device of this invention can be applied to electronic equipment which utilizes an active device. As additional examples, it is possible to make full use of the semiconductor device of this invention in facsimile devices, digital camera finders, portable televisions, DSP devices, PDAs, electronic notepads, light sign display panels, and advertising displays.

### Industrial Applicability

According to this invention, light radiation is performed on the second semiconductor layer formed over the first semiconductor layer, or on both the first semiconductor layer and the second semiconductor layer so that a structural change is induced at least in a part of the second semiconductor layer, thereby causing the structural change of the second semiconductor layer due to the light radiation to be influenced by the first semiconductor layer. The lamination manufactured in this manner shows mobility enhancement and, therefore, has high current driving ability. For example, when the lamination is applied to the semiconductor device, it exhibits excellent performance.

Because of the reason described above, the device manufactured by the manufacturing method of this invention exhibits excellent performance of electronic properties such as carrier mobility.

Since the electronic equipment which utilizes the device manufactured by the manufacturing method of this invention is composed of the device with excellent electronic properties, it can exhibit high performance.

What is claimed is:

1. A method for manufacturing a semiconductor lamination, comprising the step of performing light radiation on a second semiconductor layer formed over a first semiconductor layer, thereby inducing a structural change at least in a part of the second semiconductor layer.

2. The method for manufacturing a semiconductor lamination according to claim 1, wherein the induction of the structural change is influenced by the first semiconductor layer.

3. A method for manufacturing a semiconductor lamination, comprising the step of performing light radiation on a second semiconductor layer formed over a first semiconductor layer, thereby crystallizing at least a part of the second semiconductor layer.

4. The method for manufacturing a semiconductor lamination according to claim 3, wherein the crystallization is influenced by the first semiconductor layer.

5. The method for manufacturing a semiconductor lamination according to any one of claims 1 through 4, wherein a semiconductor layer having a crystalline area is used as the first semiconductor layer.

6. The method for manufacturing a semiconductor lamination according to any one of claims 1 through 5, wherein a semiconductor layer made of a single crystal is used as the first semiconductor layer.

7. The method for manufacturing a semiconductor lamination according to any one of claims 1 through 6, wherein a semiconductor layer formed to have an amorphous area is used as the second semiconductor layer.

8. The method for manufacturing a semiconductor lamination according to any one of claims 1 through 7, wherein a semiconductor layer exhibiting different melting behavior from that of the first semiconductor layer caused by light radiation is used as the second semiconductor layer.

9. The method for manufacturing a semiconductor lamination according to any one of claims 1 through 8, wherein a semiconductor layer having a minimum melting temperature lower than a minimum melting temperature of the first semiconductor layer is used as the second semiconductor layer.

10. The method for manufacturing a semiconductor lamination according to any one of claims 1 through 9, wherein a semiconductor layer requiring lower light energy than the light energy required to melt the first semiconductor layer is used as the second semiconductor layer.

11. The method for manufacturing a semiconductor lamination according to any one of claims 1 through 10, wherein a semiconductor layer of different composition from that of the first semiconductor layer is used as the second semiconductor layer.

12. The method for manufacturing a semiconductor lamination according to any one of claims 1 through 11, wherein two materials selected from the group consisting of composite materials containing silicon and germanium separately, and both silicon and germanium are used as materials for the first semiconductor layer and the second semiconductor layer.

13. The method for manufacturing a semiconductor lamination according to any one of claims 1 through 12, wherein a semiconductor layer having a film thickness of 100 nm or less is used as the second semiconductor layer.

14. The method for manufacturing a semiconductor lamination according to any one of claims 1 through 13, wherein light with an optical pulse width of 500 ns or less is used for the light radiation.

15. The method for manufacturing a semiconductor lamination according to any one of claims 1 through 14, wherein light with a wavelength of 600 nm or less is used for the light radiation.

16. A semiconductor device manufactured by using a semiconductor lamination manufactured by the method for manufacturing the semiconductor lamination according to any one of claims 1 through 15.

17. The semiconductor device manufactured by the method for manufacturing a semiconductor device according to claim 3 or 4, wherein at least a crystallized area in the second semiconductor layer is used as an active area of the semiconductor device.

18. The semiconductor device according to claim 17, wherein a crystallized area formed by light radiation on a silicon layer formed over a semiconductor layer made of a composite semiconductor material containing silicon and germanium is used as an active area of the semiconductor device.

19. The semiconductor device according to claim 18, wherein the substance structure of the crystallized area is different from the substance structure unique to a silicon crystal.

20. The semiconductor device according to any one of claims 16 through 18, wherein the semiconductor device is an field-effect transistor.

21. A method for manufacturing a lamination, comprising the step of performing light radiation on a second substance layer formed over a first substance layer, thereby inducing a structural change in the second substance layer.

22. The method for manufacturing a lamination according to claim 21, wherein the structural change is influenced by the first substance layer.

23. A method for manufacturing a semiconductor lamination, comprising the steps of:
forming, over a substrate, a first semiconductor layer including a first semiconductor alone, or both the first semiconductor and a second semiconductor;
forming, over the first semiconductor layer, a second semiconductor layer made of the second semiconductor; and
performing light radiation on a lamination made of the first semiconductor layer and the second semiconductor layer, thereby inducing a structural change.

24. The method for manufacturing a semiconductor lamination according to claim 23, wherein the first semiconductor is germanium.

25. The method for manufacturing a semiconductor lamination according to either claim 23 or 24, wherein the second semiconductor is silicon.

26. The method for manufacturing a semiconductor lamination according to any one of claims 23 through 25, wherein the formation of the first semiconductor layer and the formation of the second semiconductor layer are conducted continuously in a vacuum.

27. The method for manufacturing a semiconductor lamination according to any one of claims 23 through 26, wherein the first semiconductor layer includes a crystalline area.

28. The method for manufacturing a semiconductor lamination according to any one of claims 23 through 27, wherein the first semiconductor layer is formed by crystallization caused by light radiation.

29. The method for manufacturing a semiconductor lamination according to claim 28, wherein the first semiconductor layer is formed by crystallization caused by light radiation performed a plurality of times.

30. The method for manufacturing a semiconductor lamination according to either claim 28 or 29, wherein the light radiation of the first semiconductor layer is performed in a vacuum.

31. The method for manufacturing a semiconductor lamination according to any one of claims 23 through 30, wherein the light radiation of the lamination is conducted with strength of no less than an energy density capable of at least completely melting the second semiconductor layer.

32. The method for manufacturing a semiconductor lamination according to any one of claims 23 through 31, wherein the film thickness of the second semiconductor layer is 50 nm or less.

33. The method for manufacturing a semiconductor lamination according to any one of claims 23 through 32, wherein the light radiation is conducted by using a pulse laser with a pulse width of 500 ns or less.

34. The method for manufacturing a semiconductor lamination according to any one of claims 23 through 33, wherein the light radiation is conducted by using a pulse laser with a wavelength of 600 nm or less.

35. A semiconductor device manufactured by the method for manufacturing a semiconductor lamination according to any one of claims 23 through 34.

36. Electronic equipment comprising the semiconductor device according to any one of claims 16 through 20, or claim 35.
